(19) United States
(12) Patent Application Publication
(10) Pub. No.: US 2017/0010827 A1
(43) Pub. Date: Jan. 12, 2017

(54) FILE SYSTEM OF CONTROLLER

(71) Applicant: FANUC CORPORATION, Yamanashi (JP)

(72) Inventor: Akira Koizumi, Yamanashi (JP)

(73) Assignee: FANUC CORPORATION, Yamanashi (JP)

(21) Appl. No.: 15/202,800

(22) Filed: Jul. 6, 2016

(30) Foreign Application Priority Data
Jul. 10, 2015 (JP) 2015-138518

(51) Int. Cl. G06F 3/06; G06F 17/30; G11C 16/10; G11C 16/16; G11C 16/30

(52) U.S. Cl. CPC G06F 3/0619; G11C 16/16; G11C 16/30; G11C 16/10; G06F 3/064; G06F 3/0659; G06F 3/0679; G06F 17/30218

(57) ABSTRACT

A file system of a controller includes a first nonvolatile memory capable of storing a file body and first and second management information indicating storage states of the file body and a second nonvolatile memory in which first and second flags indicating write states of the first and second management information and which can quickly access. Then, when power-off occurs during data writing, when the power-off occurred is determined from states of the first and second flags stored in the second nonvolatile memory and judges whether data is normally written.

### BACKGROUND OF THE INVENTION

1. Field of the Invention

The present invention relates to a file system of a controller, and in particular, relates to a file system of a controller incapable of performing a shutdown process.

2. Description of the Related Art

A NAND flash memory is a nonvolatile memory capable of erasing and rewriting in units of blocks. Storage devices using the NAND flash memory are widely used as USB memories, SD cards, SSD (Solid State Drive) and the like.

The flash memory is rewritable, but cannot be overwritten at high speed like RAM and it is necessary to erase current data by issuing an erase command for each block before writing new data and such processes normally need a few tens of milliseconds or more. If the power supply voltage falls during data rewrite lasting a few tens of milliseconds or more, data of the block including the data may be lost or damaged. Thus, systems using a flash memory are frequently required to have a shutdown process during power-off to prevent the power supply voltage from falling while rewriting.

Particularly when updating firmware stored in a flash memory, if power-off occurs while updating, a serious system failure such as non-activation of the system in the next power-on may occur and thus, means of displaying a warning never to turn off power is frequently seen.

Many industrial devices specified that power can be turned off in any timing and no shutdown process is needed are available. Requesting a shutdown process for such industrial devices because a flash memory is internally used may lead to lower usability.

Maintaining the power supply voltage until a rewrite process is finished even if an external power supply is turned off by including a large-capacity capacitor or the like can be considered, but a long time of a few tens of milliseconds or more is needed. Adding a circuit ensuring to maintain the power supply for such a long time may lead to enlargement and a cost increase of the system.

In reality, there are many cases where even if power is turned off while rewriting, no problem is offered because a serious failure in which data is lost or damaged and the system is not normally activated does not arise. Thus, if power-off occurs while rewriting, technologies to restore the state before rewriting have been proposed (see, for example, JP 2011-215870 A and JP 2007-133535 A).

According to the technology described in JP 2011-215870 A, a backup area is secured inside a flash memory in advance and data is saved in the backup area each time rewriting is performed. In the flash memory, when power-off occurs, data may be damaged in units of blocks including the area to be rewritten. Thus, it is necessary to make a backup in units of blocks and a time of a few tens of milliseconds or more is needed for a backup process. The backup process is performed each time rewriting is performed. Such an increase in time offers no problem if the frequency of rewriting is low, but if rewriting occurs frequently in a system, a rewrite processing time increases and the system performance is seriously affected.

According to the technology described in JP 2007-133535 A, management information is held in a flash memory and when a file is created, information of double the maximum size of the file is written to the management information in advance. Then, a flag indicating which of the two pieces of data is the latest is provided and when the file is updated, the older piece of data is updated to be able to restore the state before rewriting even if power is turned off. In this system, an area of double the maximum size of a file is always used, causing a problem of low utilization efficiency of the flash memory capacity. Also, because there is only one management area, if power-off occurs when writing management information for initially creating a file, data of the management information is damaged, which makes recovery difficult. That is, a problem is posed that a system that frequently creates a new file cannot eliminate the risk of data damage by power-off.

### SUMMARY OF THE INVENTION

The present invention is made in view of the above circumstances and an object thereof is to provide a file system capable of normally activating a system even if power-off occurs while a file body is newly created or updated or management information is updated.

According to the present invention, a file system of a controller includes a processor, a first nonvolatile memory connected to the processor and erasable in blocks, a second nonvolatile memory which can access more quickly than the first nonvolatile memory, and a power supply circuit that converts a power supply input from outside. A file body and first management information and second management information indicating a storage state of the file body can be stored in the first nonvolatile memory. A first flag indicating a write state of the first management information and a second flag indicating a write state of the second management information are stored in the second nonvolatile memory. When a file is stored, the processor clears the first flag and the second flag and then newly stores the file body of the file in an available block of the first nonvolatile memory, stores the first management information in accordance with the stored file body and sets the first flag to the second nonvolatile memory, and after the first flag is set, stores the second management information in accordance with the stored file body and sets the second flag.

The file body and the first management information and the second management information indicating the storage state of the file body may be stored in the first nonvolatile memory, when a file updated to update the file body is stored, the processor may clear the first flag and the second flag and then newly store the file body of the file in an available block different from a block where the file body of the first nonvolatile memory is stored, update and store the first management information in accordance with the stored file body and set the first flag to the second nonvolatile memory, and after the first flag is set, update and store the second management information in accordance with the stored file body and set the second flag.

When creating a new file, the processor may clear the first flag and the second flag and then store the file body of the new file in an available block.

When the controller is turned on, the processor may determine states of the first flag and the second flag and when, as a result of determination, the first management information has been normally updated, activate the system using the stored file body and the first management information and when the first management information has not been normally updated, activate the system using the second management information.

According to the present invention, if power-off occurs while writing, when the power-off occurred can be judged from states of the flags stored in the nonvolatile memory which can quickly access. If it is determined that data has not been normally written by judging the flags, data immediately before writing data is restored by discarding written data. On the other hand, if it is determined that data has been normally written, the normally written data is used, thereby preventing system failures from occurring.

### BRIEF DESCRIPTION OF THE DRAWINGS

The above and other objects of the present invention will be apparent from the description below with reference to appended drawings. Among these drawings:

FIG. 1 is a block diagram showing an outline configuration of a file system of a controller according to an embodiment of the present invention;

FIG. 2 is a schematic diagram when a file is updated by the file system of the controller in FIG. 1;

FIG. 3 is a functional block diagram showing function means that functions by a system program being executed by a CPU on the controller in FIG. 1;

FIG. 4 is a flow chart showing the flow of a file update process performed by each function means shown in FIG. 3; and

FIG. 5 is a diagram illustrating file update states when power of the controller shown in FIG. 3 is turned off.

### DETAILED DESCRIPTION OF THE PREFERRED EMBODIMENTS

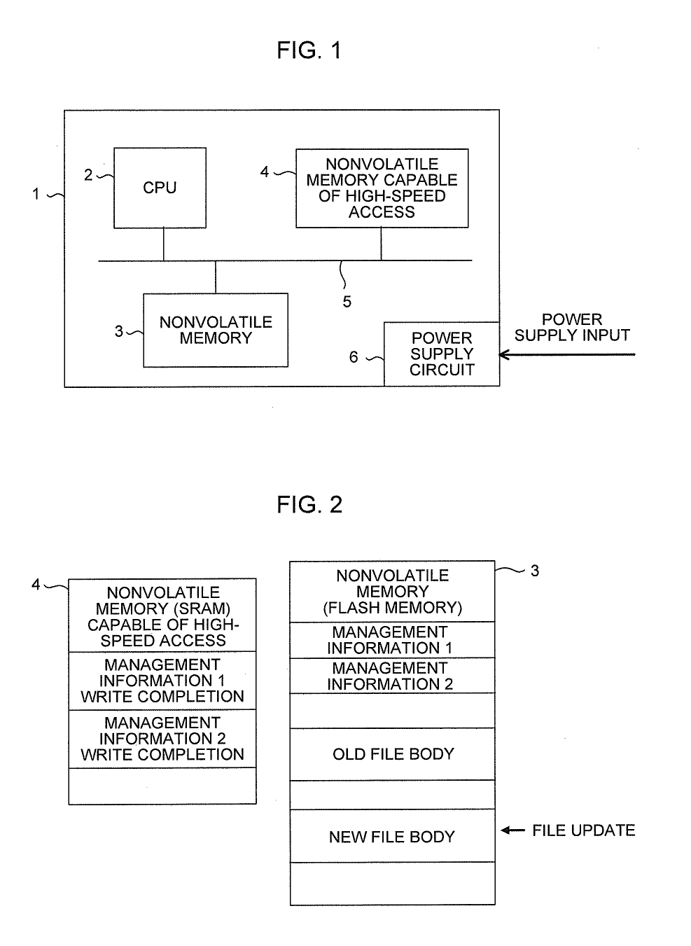

A file system of a controller according to an embodiment of the present invention will be described using FIG. 1.

In a controller 1, a nonvolatile memory 3 and a nonvolatile memory 4 which can quickly access are connected to a bus 5, which is the same bus as that of a CPU 2. A flash memory is generally used as the nonvolatile memory 3 and, for example, SRAM, MRAM, FeRAM or the like backed up by batteries is used as the nonvolatile memory 4 which can quickly access. SRAM is generally a volatile memory, but can hold data also when power of the controller 1 is turned off by being backed up by batteries and can be used as a nonvolatile memory which can quickly access. MRAM and FeRAM are nonvolatile memories and there is no need of battery backup.

Power is supplied to the controller 1 from external power supply input via a power supply circuit 6. The power supply circuit 6 can hold a short-time power supply allowing to ensure a write operation into the nonvolatile memory 4 which can quickly access also after power supply input is turned off. Ensuring a write operation into the nonvolatile memory 4 which can quickly access can be implemented by adding some electrolytic capacitors to the power supply circuit 6. For example, the access time to the nonvolatile memory 4 which can quickly access is a few hundred nanoseconds or less and thus, if the electrolytic capacitor has a capacity on the order of microfarad, the power supply during write operation can be held.

A flash memory used for the nonvolatile memory 3 is managed by being divided into sectors of a few KB to a few tens of KB and a file is stored as a list of data stored in a plurality of sectors. The inside of a flash memory is also divided, independent of sectors, into erasure units called blocks.

Management information such as sector numbers and linking of a list about the file stored in a flash memory is stored in a portion of the flash memory used for the nonvolatile memory 3 and in general, when a file is updated, a file body is updated and then, management information is updated in accordance with the new file body.

The following two cases can be considered when a file is damaged or disappears due to power-off. In one case, data of a file body is damaged by power-off when the file body is updated, whereas, in another case, management information is corrupted by power-off when the management information is updated and where the file body is stored with which linking becomes unclear.

Thus, in the present invention, as shown in FIG. 2, when a file body is updated, instead of rewriting data of sectors into which the file body has been written (‘old file body’), the updated file is written into other available sectors (such as sectors where data is invalid) as a ‘new file body’. Then, management information is updated in accordance with the file body written into new sectors. The management information is held in two different blocks (‘management information 1’, ‘management information 2’) and a flag indicating that an update is completed is stored in the nonvolatile memory 4 which can quickly access for each piece of management information. Similarly when a file body is newly stored, a file body is newly stored and then, management information is updated in accordance with the file body stored newly.

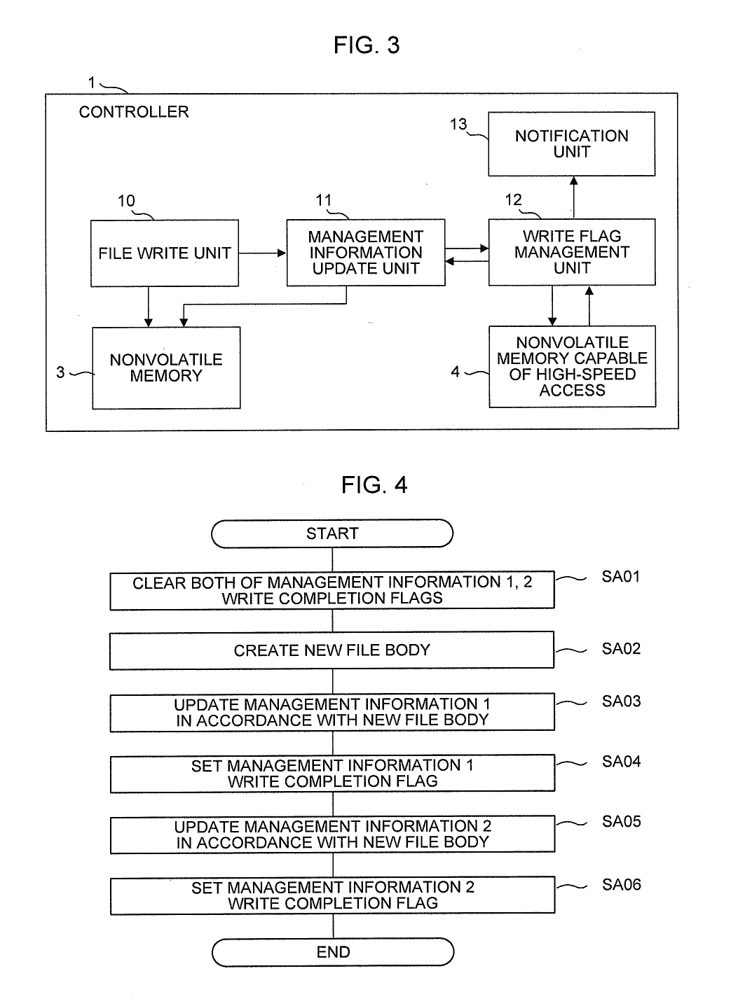

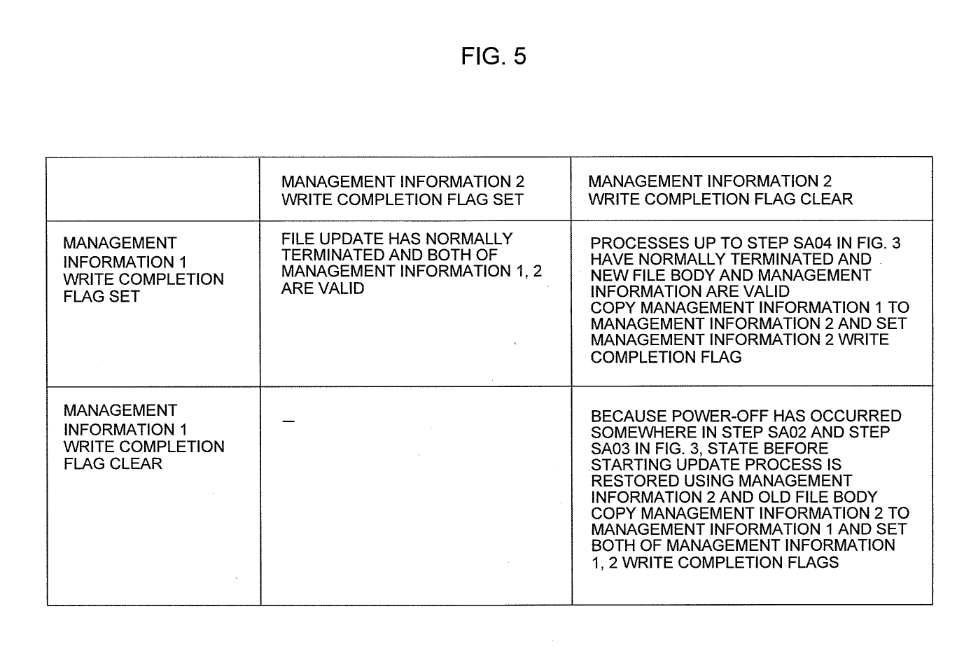

FIG. 3 shows a functional block diagram of the controller 1 according to the present embodiment and FIG. 4 is a flow chart showing the flow of a file update process performed by the controller illustrated in FIG. 3. A processor such as the CPU 2 on the controller 1 functions as each function means illustrated in FIG. 3 by a system program being executed.

[Step SA01] When the update of a file is started, a write flag management unit 12 clears both of a management information 1 write completion flag and a management information 2 write completion flag provided in the nonvolatile memory 4 which can quickly access.

[Step SA02] A file write unit 10 stores a new file body in an area different from an area of the old file body on the nonvolatile memory 3.

[Step SA03] A management information update unit 11 updates the management information 1 on the nonvolatile memory 3 in accordance with the new file body.

[Step SA04] The write flag management unit 12 sets the management information 1 write completion flag provided in the nonvolatile memory 4 which can quickly access.

[Step SA05] The management information update unit 11 updates the management information 2 on the nonvolatile memory 3 in accordance with the new file body.

[Step SA06] The write flag management unit 12 sets the management information 2 write completion flag provided in the nonvolatile memory 4 which can quickly access.

When a file is updated according to the process shown in the flowchart of FIG. 4, if power is turned off before or after the file update, patterns of the status of the management information write completion flag shown in the table of FIG. 5 can be assumed depending on the timing of power-off.

When a series of processes shown in the flowchart of FIG. 4 terminates normally without power-off during file update, the management information 1 write completion flag and the management information 2 write completion flag on the nonvolatile memory 4 which can quickly access are both set and the management information 1 and the management information 2 on the nonvolatile memory 3 are the same data. Thus, either piece of the management information may be used when file information is referred to for the next writing or reading.

On the other hand, when both of the management information 1 write completion flag and the management information 2 write completion flag are cleared, this means that power-off has occurred during the process of Step SA02 or Step SA03 in the flow chart of FIG. 4. Thus, the file system is restored to the state before starting the update process using the management information 2 and the old file body. More specifically, the file system can be restored to a normal state by copying the management information 2 on the nonvolatile memory 3 to the management information 1 and setting both of the management information 1 write completion flag and the management information 2 write completion flag on the nonvolatile memory 4 which can quickly access.

When the management information 1 write completion flag is set and the management information 2 write completion flag is cleared, processes up to Step SA04 in the flow chart of FIG. 4 has been normally terminated and the new file body and the management information 1 on the nonvolatile memory 3 are valid. Thus, the file system can be restored to a normal state by copying the management information 1 to the management information 2 on the nonvolatile memory 3 and setting the management information 2 write completion flag on the nonvolatile memory 4 which can quickly access.

Therefore, even if power-off occurs, a system is one of a “state of an updated file” and a “state before a file is updated” when activated next time. When power-off occurs when a file is initially written, a system is in one of a “state in which a correct file is written” and a “state before a file is written” and thus, the file system can be restored to a normal state by performing a recovery process of the file system in accordance with the state thereof.

If the write flag management unit 12 checks the write completion flags on the nonvolatile memory 4 which can quickly access and detects that the last file is not normally created or updated, the user may be notified of the abnormal creation or update by a notification unit 13. If the controller 1 is provided with a screen, a message is displayed on the screen as the notification unit 13 or notification can be made by using voice or buzzer or lighting up LED. Accordingly, the user can know that the last update is not normally terminated and can take appropriate measures.

According to the present invention, as described above, if power-off occurs during writing, when the power-off occurred can be judged based on states of the flags stored on the nonvolatile memory which can quickly access. System failures can be prevented from occurring by discarding written data and restoring data immediately before starting to write data when, as a result of judging the flags, it is determined that data is not normally written and by using normally written data when data is normally written.

SRAM, MRAM, FeRAM and the like used as the nonvolatile memory 4 which can quickly access can achieve access at high speed and can minimize an increase of the rewrite time to improve tolerance during power-off. In addition, the capacity consumed of the nonvolatile memory 4 which can quickly access is very slight.

While an area of double the maximum size of a file is always used in JP 2007-133535 A, in the present invention, only a net size of a file to be updated is extra used when the file is updated and better utilization efficiency of the flash memory is achieved. In addition, two pieces of management information are held and therefore, data can always be prevented from being damaged during power-off when the management information is updated.

Further, when a file is newly created, like when a file is updated, system failures can be prevented from occurring by discarding written data and restoring data immediately before starting to write data when data is not normally written and by using normally written data when data is normally written.

In the foregoing, an embodiment of the present invention has been described, but the present invention is not limited to only examples of the above embodiment and can be carried out in various forms by making appropriate alterations.

1. A file system of a controller including a processor, a first nonvolatile memory connected to the processor and erasable in blocks, a second nonvolatile memory capable of access faster than the first nonvolatile memory, and a power supply circuit that converts a power supply input from outside, wherein
a file body and first management information and second management information indicating a storage state of the file body can be stored in the first nonvolatile memory,
a first flag indicating a write state of the first management information and a second flag indicating a write state of the second management information are stored in the second nonvolatile memory,
when a file is stored, the processor clears the first flag and the second flag and then newly stores the file body of the file in an available block of the first nonvolatile memory,
stores the first management information in accordance with the stored file body and sets the first flag to the second nonvolatile memory, and
after the first flag is set, stores the second management information in accordance with the stored file body and sets the second flag.

2. The file system of a controller according to claim 1, wherein
the file body and the first management information and the second management information indicating the storage state of the file body are stored in the first nonvolatile memory,
when a file updated to update the file body is stored, the processor clears the first flag and the second flag and then newly stores the file body of the file in an available block different from a block where the file body of the first nonvolatile memory is stored,
updates and stores the first management information in accordance with the stored file body and sets the first flag to the second nonvolatile memory, and
after the first flag is set, updates and stores the second management information in accordance with the stored file body and sets the second flag.

3. The file system of a controller according to claim 1, wherein when creating a new file, the processor clears the first flag and the second flag and then stores the file body of the new file in an available block.

4. The file system of a controller according to any one of claims 1 to 3, wherein when the controller is turned on, the processor determines states of the first flag and the second flag and when, as a result of determination, the first management information has been normally updated, activates the system using the stored file body and the first management information and when the first management information has not been normally updated, activates the system using the second management information.
